(19) United States
(12) Patent Application Publication
(10) Pub. No.: US 2011/0303287 A1
(43) Pub. Date: Dec. 15, 2011

(54) SOLAR CELL MODULE AND EDGE SEALING METHOD THEREOF

(75) Inventors: Chi-Lai LEE, Taoyuan County (TW); Cheng-Pei Huang, Taipei City (TW)

(73) Assignee: Du Pont Apollo Limited, Hong Kong (HK)

(21) Appl. No.: 13/115,979

(22) Filed: May 25, 2011

(30) Foreign Application Priority Data
Jun. 11, 2010 (CN) 201010213680.7

(51) Int. Cl. H01L 31/0203; C03C 27/00

(52) U.S. Cl. 136/259; 65/43

(57) ABSTRACT

A solar cell module and an edge sealing method thereof are provided. The edge sealing method includes the following steps: providing a solar cell unit, which sequentially has an upper glass substrate, an intermediate and a lower glass substrate; heating and softening glass materials and fill the glass materials fully in a clearances between edges of the upper glass substrate and edges of the lower glass substrate; and cooling down the glass materials, such that the glass materials are formed into one piece with the upper glass substrate and the lower glass substrate and seal the intermediate.

### RELATED APPLICATIONS

This application claims priority to China Application Serial Number 201010213680.7, filed Jun. 11, 2010, which is herein incorporated by reference.

### BACKGROUND

1. Field of Invention

The present invention relates to a solar cell module fabrication method. More particularly, the present invention relates to an edge sealing method of a solar cell module.

2. Description of Related Art

After fabrication, a completed conventional crystalline photovoltaic module needs to pass multiple quality control tests such as an insulation test, an outdoor exposure test and a damp heat test in IEC 61215: Crystalline Silicon Terrestrial Photovoltaic Modules—Design Qualification or Type Approval and IEC 61646: Thin-film Terrestrial Photovoltaic Modules Design Qualification and Type Approval, thereby selecting qualified solar cell modules.

The damp heat test aims to test the resistance capability of a solar cell module against long-term damp permeation. For example, when a solar cell module under test goes through a reliability test of the damp heat test, the solar cell module under test has to be able to suffer a 1000-hour test under a high-temperature and high-humidity environment (for example, 85° C. temperature and 85% humidity) and still maintain certain acceptable performance.

To pass the reliability test of the damp heat test, solar cell manufacturers currently wrap all the edges of a solar cell module with a waterproof adhesive tape or rubber sealing stripe to prevent moisture penetration as much as possible.

However, although all the edges of the solar cell module are wrapped with the aforementioned waterproof adhesive tape or rubber sealing stripe, the moisture still cannot be effectively prevented from penetrating into the solar cell module via clearances of the solar cell module, and thus the moisture absorption of the materials inside the solar cell module is aggravated, thus increasing the risk of damaging the solar cell module.

Furthermore, when all the edges of the solar cell module are wrapped with a waterproof adhesive tape or rubber sealing stripe, manufacturers may need to add a protective member (for example, a frame pad) outside the waterproof adhesive tape or rubber sealing stripe so as to protect the aforementioned waterproof material from being damaged by stress, thus not only increasing the material coast but also increasing the volume of the solar cell module, further reducing the number of solar cell modules accommodated in one unit area.

Therefore, there is a need for those who are in this industry to provide a solution for effectively preventing moisture penetration into the solar cell module and meanwhile maintaining the original volume of the solar cell module.

### SUMMARY

An object of the present invention is to provide a solar cell module and a fabrication method thereof, thereby effectively preventing moisture from penetrating into the solar cell module; and further greatly overcoming the moisture absorption problem of the materials inside the solar cell module.

Another object of the present invention is to provide a solar cell module and a fabrication method thereof, thereby avoiding the appearance problems of crack and adhesion subsequently occurring in a conventional rubber sealing stripe.

Another object of the present invention further is to provide a solar cell module and a fabrication method thereof, in which the protective member for protecting the waterproof material can be removed and the original volume of the solar cell module can be maintained.

In an aspect of the present invention, an edge sealing method of a solar cell module is provided, and includes the following steps: providing a solar cell unit, wherein the solar cell unit includes an upper glass substrate, a lower glass substrate and an intermediate located therebetween; heating and softening a plurality of glass materials and filling the softened glass materials fully in clearances formed between edges of the upper glass substrate and edges of the lower glass substrate; and cooling down the glass materials, such that the glass materials are formed into one piece with the upper glass substrate and the lower glass substrate and seal the intermediate.

According to an embodiment of the present invention, in the step of providing the solar cell unit, each of the edges of the upper glass substrate has a first slant surface, and each of the edges of the lower glass substrate has a second slant surface, wherein one of the clearances is formed between the corresponding first slant surface and second slant surface.

According to another embodiment of the present invention, in the step of providing the solar cell unit, the edges of the lower glass substrate respectively have flanges extending towards the same direction and the flanges enclose the upper glass substrate. In this embodiment, each of the edges of the upper glass substrate has a third slant surface, and each of the edges of the flanges has a fourth slant surface, wherein one of the clearances is formed between the corresponding third slant surface and fourth slant surface.

According to yet another embodiment of the present invention, the step of heating and softening the glass materials and filling the softened glass materials fully in the clearances further includes: placing a plurality of solid-state glass materials in the clearances and using a heating device to heat the solid-state glass materials in the clearances to reach a specific temperature until the solid-state glass materials are softened.

According to yet another embodiment of the present invention, the step of heating and softening the glass materials and filling the softened glass materials fully in the clearances further includes: overturning the solar cell unit to make one of the clearances face towards a direction opposite to gravity direction, and providing the softened glass materials into the clearances in the gravity direction, thereby allowing the softened glass materials to flow inside the clearances.

In another aspect of the present invention, a solar cell module fabricated according to the aforementioned method is provided, and includes an upper glass substrate, a lower glass substrate, an intermediate and a glass periphery. The intermediate is located between the upper glass substrate and the lower glass substrate. The glass periphery is located between all the edges of the upper glass substrate and all the edges of the lower glass substrate, and is formed into one piece with the upper glass substrate and the lower glass substrate so as to surround and seal the intermediate.

According to another embodiment of the present invention, the intermediate includes an encapsulating material and a solar cell. In this embodiment, the encapsulating material includes ethylene vinyl acetate copolymer.

Compared with the prior art, the present invention seal edges of a solar cell module by using melted glass materials integrally joined in the clearances at the edges of the solar cell unit, thus greatly reducing the clearances through which the moisture penetrates; effectively preventing moisture from penetrating into the solar cell module; and further greatly improving the moisture absorption problem of materials in the solar cell module and prolonging a product life cycle.

### BRIEF DESCRIPTION OF THE DRAWINGS

The invention can be more fully understood by reading the following detailed description of the embodiments, with reference made to the accompanying drawings as follows:

FIG. 1 is a flow chart showing an edge sealing method of a solar cell module according to the present invention;

FIG. 2A is a schematic view of a solar cell unit;

FIG. 2B is a schematic view showing an edge sealing operation performed on the solar cell unit shown in FIG. 2A according to an embodiment of the present invention;

FIG. 3A is a schematic view of another solar cell unit;

FIG. 3B is a schematic view showing an edge sealing operation performed on the solar cell unit shown in FIG. 3A according to another embodiment of the present invention;

FIG. 4 is a partial side view of the solar cell module after the edge sealing is completed;

FIG. 5 is a schematic view showing an edge sealing operation performed on another solar cell unit; and

FIG. 6 is a schematic view showing an edge sealing operation performed on yet another solar cell unit.

### DETAILED DESCRIPTION

The present invention provides an edge sealing method of solar cell module and a solar cell module fabricated by using this method. According to the edge sealing method, a melted glass material is filled fully in the clearance at the edges of the solar cell module through which moisture is likely to penetrate, such that after being cooled down, the glass material may be joined with the glass substrates at two sides of the solar cell module into one piece, thus forming a glass container having a closed space. In this way, the edges of the solar cell module can be sealed to effectively prevent moisture from penetrating into the solar cell module and further greatly improve the moisture absorption problem of materials inside the solar cell module.

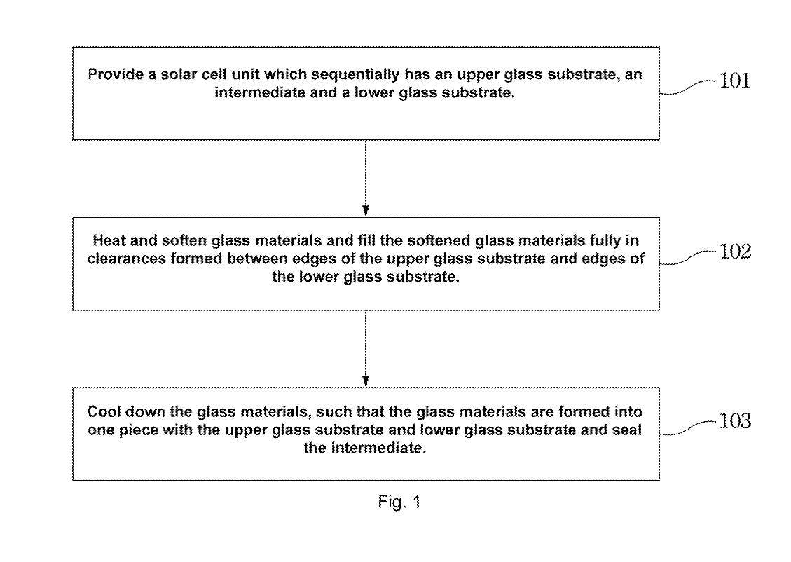

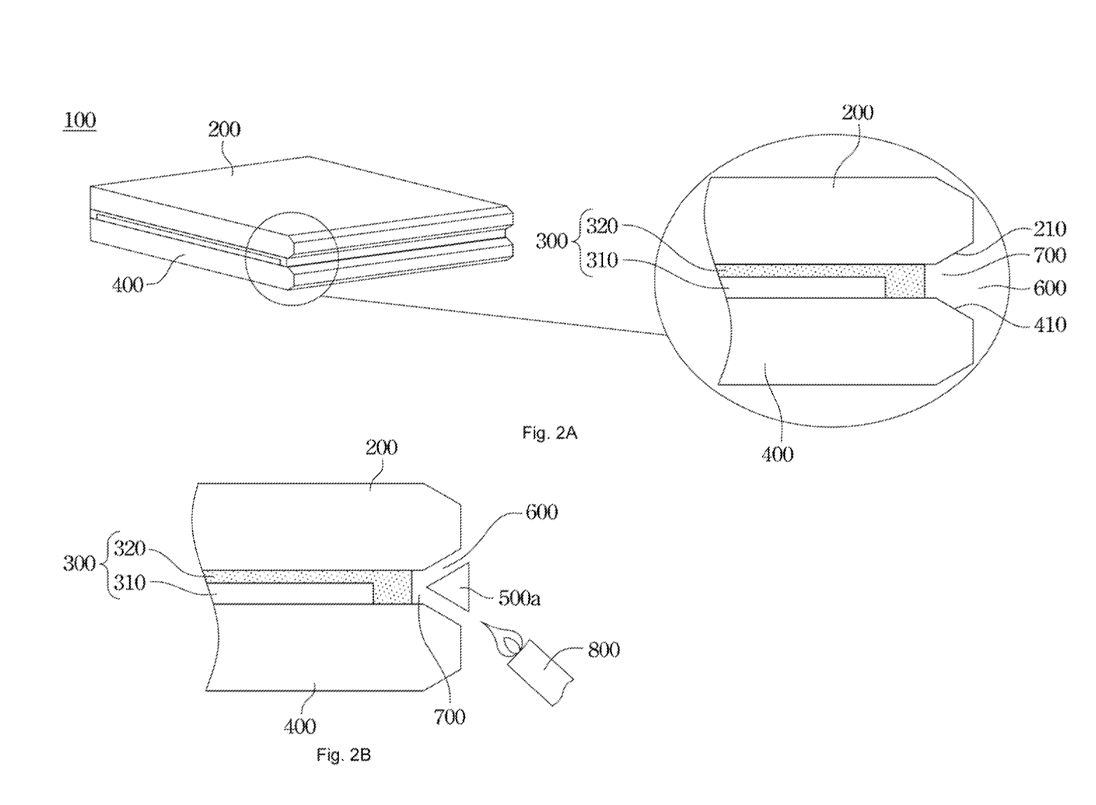

Referring to FIG. 1, FIG. 2A and FIG. 2B, FIG. 1 is a flow chart showing an edge sealing method of a solar cell module according to the present invention; FIG. 2A is a schematic view of a solar cell unit; and FIG. 2B is a schematic view showing an edge sealing operation performed on the solar cell unit shown in FIG. 2A according to an embodiment of the present invention.

The edge sealing method of the solar cell module includes the following steps:

In step 101, a solar cell unit 100 is provided, and the solar cell unit 100 sequentially has an upper glass substrate 200, an intermediate 300 and a lower glass substrate 400 (as shown in FIG. 2A).

In step 102, a plurality of glass materials 500a are heated and softened, and are fully filled in clearances 600 formed between edges of the upper glass substrate 200 and edges of the lower glass substrate 400 (as shown in FIG. 2B).

In step 103, the softened glass materials 500a are cooled down, such that the glass materials 500a are formed into one piece with the upper glass substrate 200 and lower glass substrate 400, and the intermediate 300 is sealed between the upper glass substrate 200 and the lower glass substrate 400.

Furthermore, referring to FIG. 2A again, step 101 shown in FIG. 1 is performed to prepare a solar cell unit 100, and is a preparation procedure for the edge sealing. The intermediate 300 is located in an accommodation space 700 sandwiched between the upper glass substrate 200 and the lower glass substrate 400.

Specifically, the upper glass substrate 200 and the lower glass substrate 400 are substantially rectangular plates, and the area of each of their two opposite surfaces is greater than the surface area of the intermediate 300, and thus clearances 600 are formed respectively between all the edges of the upper glass substrate 200 and all the edges of the lower glass substrate 400, and each clearance 600 communicates with the accommodation space 700.

It needs to be defined that the upper glass substrate 200 and the lower glass substrate 400 are both fabricated from a glass material and the intermediate 300 generally refers to all the components between the upper glass substrate 200 and the lower glass substrate 400 in the solar cell unit 100, which are collectively referred to as a solar cell 310. The solar cell 310 is directly formed on one of the glass substrates (as shown in FIG. 2A, for example, the lower glass substrate 400), and then an encapsulating material 320 (for example, ethylene-vinyl acetate copolymer, EVA) having a high moisture absorption capability and another glass substrate (as shown in FIG. 2A, for example, the upper glass substrate 200) are sequentially placed on the solar cell 310, for performing press bonding. In this way, the solar cell 310 can be encapsulated in the accommodation space 700.

Furthermore, in practice, all the edges of the glass substrate are respectively designed with bevels for preventing the edges of glass substrate from being cracked in the course of moving or assembling. As to all the edges of the upper glass substrate 200, for example, each bevel of the upper glass substrate 200 has a first slant surface 210 facing towards the lower glass substrate 400 (as shown in FIG. 2A). As to all the edges of the lower glass substrate 400, for example, each bevel of the lower glass substrate 400 has a second slant surface 410 facing towards the upper glass substrate 200. One clearance 600 (for example, about 1 mm-2 mm) described above can be formed between the corresponding first slant surface 210 and the second slant surface 410.

Step 102 shown in FIG. 1 may be implemented according to the following two embodiments. However, such two embodiments are merely exemplary and do not intend to limit the scope of the present invention. The softened glass materials 500a may be filled fully in the clearances 600 between the upper glass substrate 200 and the lower glass substrate 400 in another manner, which also falls within the scope of the present invention.

As shown in FIG. 2A and FIG. 2B, step 102 shown in FIG. 1 according to one embodiment includes:

(i) placing a plurality of solid-state glass materials 500a (for example, glass fibers or glass rods) in the aforementioned clearances 600; and

(ii) using a heating device 800 (for example, a blast lamp) to heat the solid-state glass materials 500a in the clearances 600 to a specific temperature (e.g. 500° C. to 700° C.) until the solid-state glass materials 500a are softened to form a fluid which is transformed from a solid state to a liquid state.

Furthermore, since the heating device 800 produces a thermal airflow, the thermal airflow pushes the softened glass materials 500a into the clearances 600 (i.e. in the direction of the accommodation space 700) until the softened glass materials 500a are filled fully in the accommodation space 700 and uniformly seal the clearance 600.

Operators also may selectively perform the aforementioned edge sealing operation on all or some of the clearances 600 and provide a frame pad for protection as required.

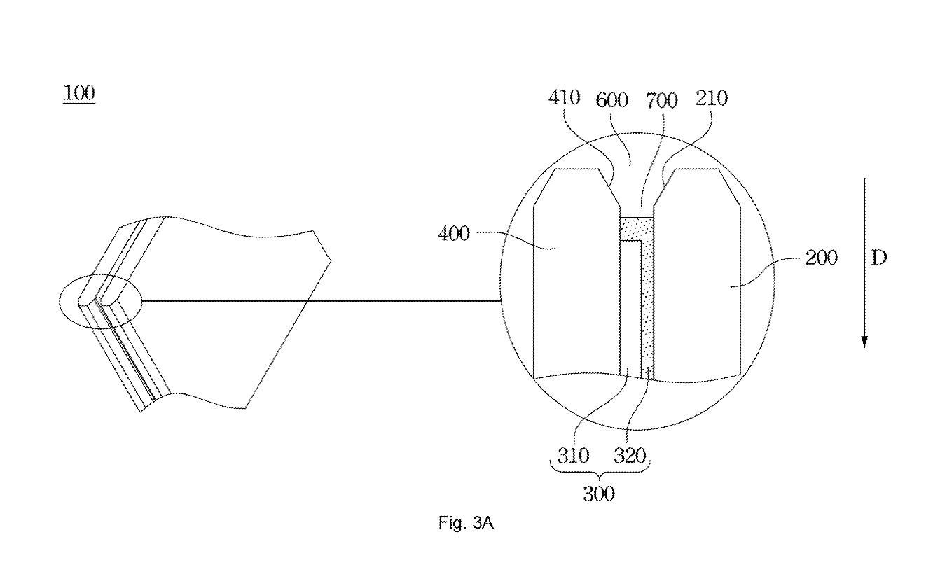

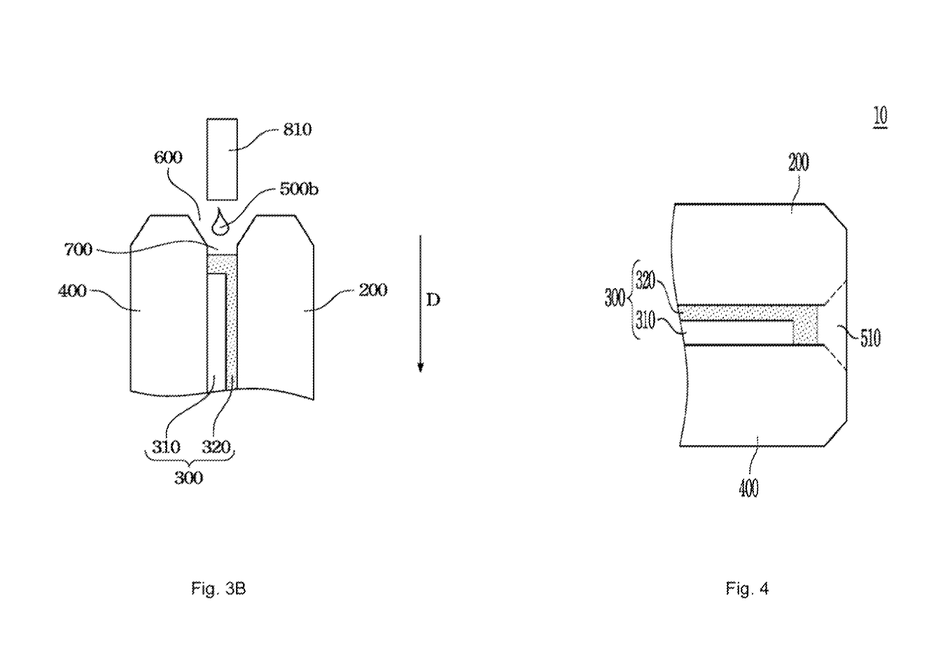

Referring to FIGS. 3A and 3B, FIG. 3A is a schematic view of another solar cell unit, and FIG. 3B is a schematic view showing an edge sealing operation performed on the solar cell unit shown in FIG. 3A according to another embodiment of the present invention.

Step 102 of FIG. 1 according to another embodiment includes:

(i) overturning the solar cell unit 100 to change the facing direction of the clearance 600 of the solar cell unit 100, so that the clearance 600 faces a direction opposite to gravity direction D (as shown in FIG. 3A); and

(ii) heating and softening a solid-state glass material (e.g. glass fibers or glass rods) in advance to make the glass material transformed from a solid state to a liquid state, and providing the softened glass material 500b through a transportation tool 810 in the gravity direction D, for example, in a vertical manner, into the clearance 600 until the softened glass material 500b is filled fully in the accommodation space 700 and uniformly seals the clearance 600 (FIG. 3B).

Likewise, operators may selectively perform the aforementioned edge sealing operation on all or some of the clearances 600 and provide a frame pad for protection as required.

It should be explained that the aforementioned “heating and softening” or “softening” means that the glass transformed from a solid state to a liquid state having plasticity after being heated.

Furthermore, since the softening temperature at which the glass is softened from a solid state to a liquid state is referred to as a softening point, the softening point is 1500° C. when the glass substrate is quartz glass, and is 900° C. when the glass substrate is Pyrex. The softening point of the glass materials 500a is substantially 500° C.-700° C. Therefore, when the glass materials 500a are softened under heat, its temperature does not reach the softening point of the glass substrate, and thus the glass substrate is not softened and deformed. Further, the glass materials may be doped with different amounts of iron so as to form glass with strengthening characteristics.

Referring to FIG. 1 and FIG. 4, FIG. 4 is a partial side view of the solar cell module after the edge sealing is completed.

After the glass materials 500a and 500b (shown in FIG. 2B and FIG. 3B) in Step 103 of FIG. 1 are cooled down, the glass materials 500a and 500b filled in the accommodation space 700 and the clearances 600 are formed into one piece with the upper glass substrate 200 and the lower glass substrate 400, thus completely sealing the intermediate 300 in the accommodation space 700. Thus, a solar cell module 10 having a closed space is formed.

Specifically, when the softened glass materials 500a and 500b are not heated any more, the glass materials 500a and 500b are cooled down to the room temperature naturally, and further, in the clearances 600 of the solar cell module 10, joined with the upper glass substrate 200 and the lower glass substrate 400 into one piece, thus forming a glass periphery 510 that surrounds and seals the intermediate 300 (as shown in FIG. 4). Definitely, operators also may select another active method for cooling down the glass materials 500a and 500b according to requirements and limitations (for example, providing cold air).

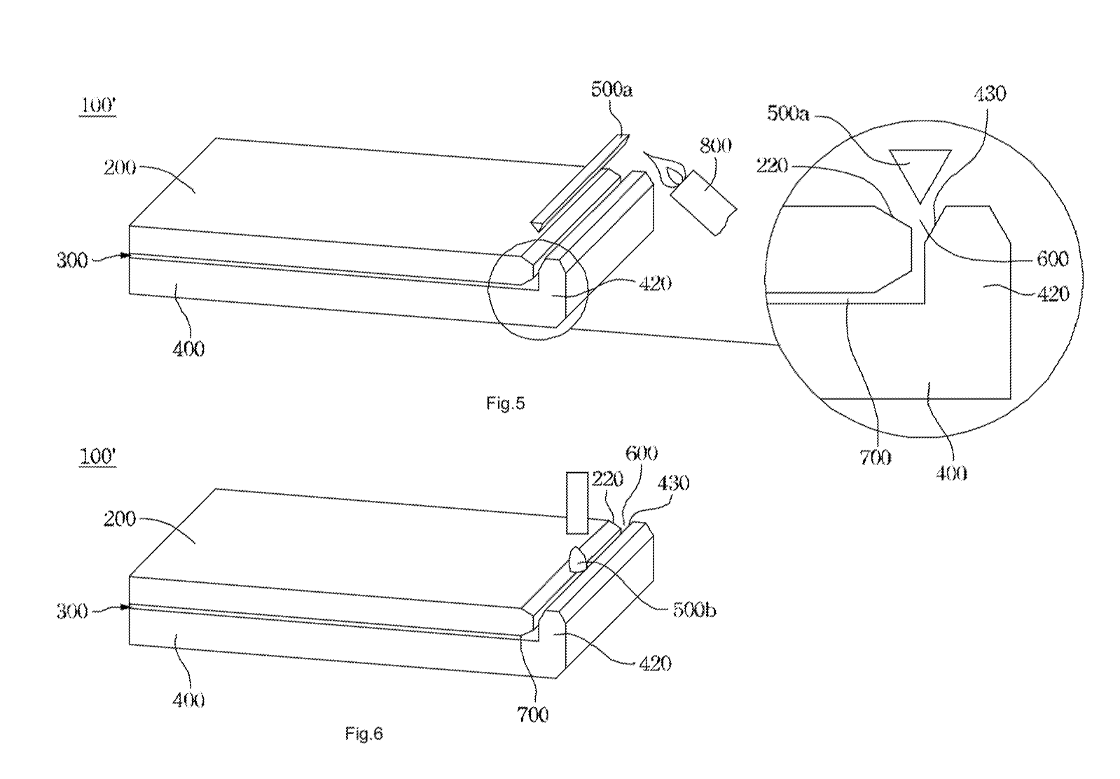

Referring to FIG. 5 and FIG. 6, FIG. 5 is a schematic view showing an edge sealing operation performed on another solar cell unit, and FIG. 6 is a schematic view showing edge sealing operation performed on yet another solar cell unit. All the edges of the lower glass substrate 400 of another solar cell unit 100′ respectively have flanges 420 extending towards the same direction (e.g. towards the upper glass substrate 200), and the flanges 420 collaboratively enclose the upper glass substrate 200 and the intermediate 300.

Each of the edges of the upper glass substrate 200, for example, each bevel of the upper glass substrate 200, has a third slant surface 220 facing towards a direction away from the intermediate 300. Each of the flanges 420 of the edges of the lower glass substrate 400, for example, each bevel of the flanges 420, has a fourth slant surface 430 facing towards the upper glass substrate 200. The aforementioned clearance 600 (for example, about 1-2 mm) can be formed between the corresponding third slant surface 220 and fourth slant surface 430. In this way, operators may base on requirements and limitations to select an edge sealing method according to any embodiment in Step (102) of FIG. 1.

Compared with the problem in the prior art that a clearance 600 through which the moisture penetrates still exists between the solar cell module and the waterproof adhesive tape, the rubber sealing stripe or even the frame pad, the present invention integrally joins the melted glass materials in the clearances 600 at the edges of the solar cell unit, thereby sealing the edges of the solar cell unit, thus greatly reducing the clearances 600 through which the moisture penetrates and effectively preventing moisture from penetrating into the solar cell module, and further greatly improving the moisture absorption problem of materials in the solar cell module. Furthermore, since the glass materials and the upper and lower glass substrates 400 have similar characteristics, designers do not need to consider whether disadvantageous chemical changes will occur, and the glass materials can be joined with the upper and the lower glass substrates 400 into one piece so as to form a glass container having a closed space to surround and seal the intermediate 300 therein.

Although the present invention has been described in considerable detail with reference to certain embodiments thereof, other embodiments are possible. Various alternations and modifications can be made to these certain embodiments by those skilled in the art without departing from the spirit and scope of the present invention. Such alternations and modifications are intended to fall within the scope of the appended claims.

What is claimed is:

1. An edge sealing method of a solar cell module, comprising:
providing a solar cell unit, wherein the solar cell unit comprises an upper glass substrate, a lower glass substrate and an intermediate, and the intermediate is located between the upper glass substrate and the lower glass substrate;
heating and softening a plurality of glass materials and filling the softened glass materials fully in clearances formed between edges of the upper glass substrate and edges of the lower glass substrate; and
cooling down the softened glass materials, such that the glass materials are formed into one piece with the upper glass substrate and lower glass substrate and seal the intermediate.

2. The edge sealing method of claim 1, wherein in the step of providing the solar cell unit, each of the edges of the upper glass substrate has a first slant surface, and each of the edges of the lower glass substrate has a second slant surface, wherein one of the clearances is formed between the corresponding first slant surface and second slant surface.

3. The edge sealing method of claim 1, wherein in the step of providing the solar cell unit, all the edges of the lower glass substrate respectively have flanges extending towards the same direction, and the flanges enclose the upper glass substrate.

4. The edge sealing method of claim 3, wherein each of the edges of the upper glass substrate has a third slant surface, and each of the edges of the flanges has a fourth slant surface, wherein one of the clearances is formed between the corresponding third slant surface and fourth slant surface.

5. The edge sealing method of claim 1, wherein the step of heating and softening the glass materials and filling the softened glass materials fully in the clearances further comprises:
placing a plurality of solid-state glass materials in the clearances; and
using a heating device to heat the solid-state glass materials in the clearances to a specific temperature until the solid-state glass materials are softened.

6. The edge sealing method of claim 1, wherein the step of heating and softening the glass materials and filling the softened glass materials fully in the clearances further comprises:
overturning the solar cell unit to make one of the clearances face towards a direction opposite to gravity direction; and
providing the soften glass materials into the clearance in the gravity direction, thereby allowing the softened glass materials to flow inside the clearances.

7. A solar cell module, comprising:
an upper glass substrate;
a lower glass substrate;
an intermediate located between the upper glass substrate and the lower glass substrate; and
a glass periphery which is located between edges of the upper glass substrate and edges of the lower glass substrate, and formed into one piece with the upper glass substrate and the lower glass substrate for surrounding and sealing the intermediate.

8. The solar cell module of claim 7, wherein the intermediate comprises an encapsulating material and a solar cell.

9. The solar cell module of claim 8, wherein the encapsulating material comprises ethylene vinyl acetate copolymer.
